(19) United States
(12) Patent Application Publication
(10) Pub. No.: US 2013/0062743 A1
(43) Pub. Date: Mar. 14, 2013

(54) POWER MODULE PACKAGE AND METHOD FOR MANUFACTURING THE SAME

(71) Applicants: Kwang Soo Kim, Gyunggi-do (KR); Young Ki Lee, Gyunggi-do (KR); Young Hoon Kwak, Gyunggi-do (KR)

(72) Inventors: Kwang Soo Kim, Gyunggi-do (KR); Young Ki Lee, Gyunggi-do (KR); Young Hoon Kwak, Gyunggi-do (KR)

(73) Assignee: SAMSUNG ELECTRO-MECHANICS CO., LTD., Gyunggi-do (KR)

(21) Appl. No.: 13/304,230

(22) Filed: Nov. 23, 2011

(30) Foreign Application Priority Data
Sep. 14, 2011 (KR) 1020110092591

(51) Int. Cl. H01L 23/34; H01L 21/50

(52) U.S. Cl. 257/675; 438/122; 257/E23.08; 257/E21.499

(57) ABSTRACT

Disclosed herein are a power module package and a method for manufacturing the same. The power module package includes: a heat dissipation plate including a first heat dissipation plate and a second heat dissipation plate disposed to be spaced apart from each other; insulating layers formed on the heat dissipation plate; metal layers formed on the insulating layers, semiconductor devices mounted on the metal layers; and lead spacers formed to connect the metal layer of the first heat dissipation plate side or the metal layer of the second heat dissipation plate side with the semiconductor layers, wherein the semiconductor devices formed on the metal layers of the first heat dissipation plate side and the semiconductor devices formed on the metal layer of the second heat dissipation plate side are disposed in a multi-layered type.

### CROSS REFERENCE TO RELATED APPLICATION

This application claims the benefit of Korean Patent Application No. 10-2011-0092591, filed on Sep. 14, 2011, entitled “Power Module Package and Method for Manufacturing the Same”, which is hereby incorporated by reference in its entirety into this application.

### BACKGROUND OF THE INVENTION

1. Technical Field

The present invention relates to a power module package and a method for manufacturing the same.

2. Description of the Related Art

With the increase in energy consumption around the world, an efficient use of restricted energy has been attracting much attention. Therefore, a use of an inverter adopting an intelligent power module (IPM) for efficiently converting energy in the existing home and industrial appliances has accelerated.

With the increase in the use of the power module, a demand in a market for high-integration, high-capacity, and small-sized products has increased. As a result, a solution for a problem of heat generation from electronic parts has emerged as an important issue.

In particular, when using a high-capacity power device (for example, a high-capacity insulated gate bipolar transistor (IGBT), or the like), heat generated from a high heat generation power device affects a control device that is relatively vulnerable to heat, thereby degrading the entire performance of a module and long-term reliability.

As a result, as a method for solving the heat generation problem so as to increase efficiency of a power module and secure high reliability, a structure for separately manufacturing a power module and a water cooling system and coupling the power module and the water cooling system has been considered.

However, the above-mentioned coupling structure may increase costs for manufacturing the power module and the water cooling system, respectively, and have difficulties in a change in a design and miniaturization.

### SUMMARY OF THE INVENTION

The present invention has been made in an effort to provide a power module package and a method for manufacturing the same capable of more effectively emitting heat generated from semiconductor devices by implementing a cooling channel through which a cooling material flows into a top portion and a bottom portion.

In addition, the present invention has been made in an effort to implement three-dimensionally high integration by disposing semiconductor devices in a multi-layered type.

According to an exemplary embodiment of the present invention, there is provided a power module package, including: a heat dissipation plate including a first heat dissipation plate and a second heat dissipation plate disposed to be spaced apart from each other; insulating layers formed on the heat dissipation plate; metal layers formed on the insulating layers, semiconductor devices mounted on the metal layers; and lead spacers formed to connect the metal layer of the first heat dissipation plate side or the metal layer of the second heat dissipation plate side with the semiconductor layers, wherein the semiconductor devices formed on the metal layers of the first heat dissipation plate side and the semiconductor devices formed on the metal layer of the second heat dissipation plate side are disposed in a multi-layered type.

One side of the lead spacer may be formed to connect between the multi-layered semiconductor devices and the other side thereof may be formed to connect to the metal layer of the first heat dissipation plate side or the metal layer of the second heat dissipation plate side.

When the multi-layered semiconductor devices are configured with two pairs and the lead spacer includes a first lead spacer and a second lead spacer, sides of the first and second lead spacers may be formed to connect between the multi-layered semiconductor devices and the other sides thereof may be formed to connect to the metal layer of the first heat dissipation plate side.

When the multi-layered semiconductor devices are configured with two pairs and the lead spacer includes the first lead spacer and the second spacer, one side of the first lead spacer may be formed to connect between the multi-layered semiconductor devices and the other side thereof may be formed to connect to the metal layer of the first heat dissipation plate side and one side of the second lead spacer may be formed to connect between the multi-layered semiconductor devices and the other side thereof may be formed to connect to the metal layer of the second heat dissipation plate side.

One side of the lead spacer may be formed to connect to the metal layer of the first heat dissipation plate side, a central region thereof may be formed to be inserted between the multi-layered semiconductor devices, and the other side thereof may be formed to connect to the metal layer of the second heat dissipation plate side.

When the multi-layered semiconductor devices are configured with two pairs and the lead spacer includes the first lead spacer and the second spacer, one side of the first lead spacer may be formed to connect between the multi-layered semiconductor devices and the other side thereof may be formed to connect to the metal layer of the first heat dissipation plate side and one side of the second lead spacer may be formed to connect to the metal layer of the first heat dissipation plate side, a central region thereof may be formed to be inserted between the multi-layered semiconductor devices, and the other side thereof may be formed to connect to the metal layer of the second heat dissipation plate side.

The power module package may further include a cooling channel formed so as to move a cooling material to the inside of the heat dissipation plate.

The cooling channel may be formed at a center of the heat dissipation plate based on a thickness direction of the heat dissipation plate.

The semiconductor device may include power devices and control devices and the power devices may be mounted on the metal layer of the first heat dissipation plate side and the control devices may be mounted on the metal layer of the second heat dissipation plate side.

When the semiconductor devices include power devices and control devices and the multi-layered semiconductor devices are configured with two pairs, the power devices may each be mounted on the metal layer of the first heat dissipation plate side or the metal layer of the second heat dissipation plate side and the control devices may each be mounted on the metal layer of the first heat dissipation plate side or the metal layer of the second heat dissipation plate side.

The semiconductor devices may include control devices and the control devices may be mounted on the metal layer of the first heat dissipation plate side or the metal layer of the second heat dissipation plate side.

According to another exemplary embodiment of the present invention, there is provided a method for manufacturing a power module package, including: preparing a heat dissipation plates including a first heat dissipation plate and a second heat dissipation plate; forming insulating layers on the heat dissipation plate; forming metal layers on the insulating layers; mounting semiconductor devices on the metal layers; and forming lead spacers to connect the first heat dissipation plate or the second heat dissipation plate with the semiconductor devices to couple the first heat dissipation plate and the second heat dissipation plate and disposing the second heat dissipation plate on the first heat dissipation plate so as to be spaced apart from the first heat dissipation plate, wherein the semiconductor devices formed on the metal layers of the first heat dissipation plate side and the semiconductor devices formed on the metal layer of the second heat dissipation plate side are disposed in a multi-layered type.

At the disposing of the second heat dissipation plate on the first heat dissipation plate so as to be spaced apart from the first heat dissipation plate, one side of the lead spacer may be formed to connect between the multi-layered semiconductor devices and the other side thereof may be formed to connect to the metal layer of the first heat dissipation plate side or the metal layer of the second heat dissipation plate side.

When the multi-layered semiconductor devices are configured with two pairs and the lead spacer includes a first lead spacer and a second lead spacer, sides of the first and second lead spacers may be formed to connect between the multi-layered semiconductor devices and the other sides thereof may be formed to connect to the metal layer of the first heat dissipation plate side.

When the multi-layered semiconductor devices are configured with two pairs and the lead spacer includes the first lead spacer and the second spacer, one side of the first lead spacer may be formed to connect between the multi-layered semiconductor devices and the other side thereof may be formed to connect to the metal layer of the first heat dissipation plate side and one side of the second lead spacer may be formed to connect between the multi-layered semiconductor devices and the other side thereof may be formed to connect to the metal layer of the second heat dissipation plate side.

At the disposing of the second heat dissipation plate on the first heat dissipation plate so as to be spaced apart from the first heat dissipation plate, one side of the lead spacer may be formed to connect to the metal layer of the first heat dissipation plate side, a central region thereof may be formed to be inserted between the multi-layered semiconductor devices, and the other side thereof may be formed to connect to the metal layer of the second heat dissipation plate side.

At the disposing of the second heat dissipation plate on the first heat dissipation plate so as to be spaced apart from the first heat dissipation plate, when the multi-layered semiconductor devices are configured with two pairs and the lead spacer includes the first lead spacer and the second lead spacer, one side of the first lead spacer may be formed to connect between the multi-layered semiconductor devices and the other side thereof may be formed to connect to the metal layer of the first heat dissipation plate side and one side of the second lead spacer may be formed to connect to the metal layer of the first heat dissipation plate side, a central region thereof may be formed to be inserted between the multi-layered semiconductor devices and the other side thereof may be formed to connect to the metal layer of the second heat dissipation plate side.

The method may further include: at the preparing of the heat dissipation plate, forming a cooling channel so as to move a cooling material to the inside of the heat dissipation plate.

At the mounting of the semiconductor device, when the semiconductor device includes power devices and control devices, the power devices may be mounted on the metal layer of the first heat dissipation plate side and the control devices may be mounted on the metal layer of the second heat dissipation plate side.

At the mounting of the semiconductor devices, when the semiconductor devices include power devices and control devices and the multi-layered semiconductor devices are configured with two pairs, the power devices may each be mounted on the metal layer of the first heat dissipation plate side or the metal layer of the second heat dissipation plate side and the control devices may each be mounted on the metal layer of the first heat dissipation plate side or the metal layer of the second heat dissipation plate side.

### BRIEF DESCRIPTION OF THE DRAWINGS

FIG. 1 is a cross-sectional view showing a structure of a power module package according to a first preferred embodiment of the present invention.

FIG. 2 is a cross-sectional view showing a structure of a power module package according to a second preferred embodiment of the present invention.

FIG. 3 is a cross-sectional view showing a structure of a power module package according to a third preferred embodiment of the present invention.

FIG. 4 is a diagram for explaining a disposition example of semiconductor devices according to the preferred embodiment of the present invention.

FIG. 5 is a flow chart for explaining a method for manufacturing a power module package according to the preferred embodiment of the present invention.

### DESCRIPTION OF THE PREFERRED EMBODIMENTS

Various features and advantages of the present invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Terms used in the specification, ‘first’, ‘second’, etc. can be used to describe various components, but the components are not to be construed as being limited to the terms. The terms are only used to differentiate one component from other components.

Hereinafter, the preferred embodiments of the present invention will be described in detail with reference to the accompanying drawings.

Power Module Package-First Preferred Embodiment

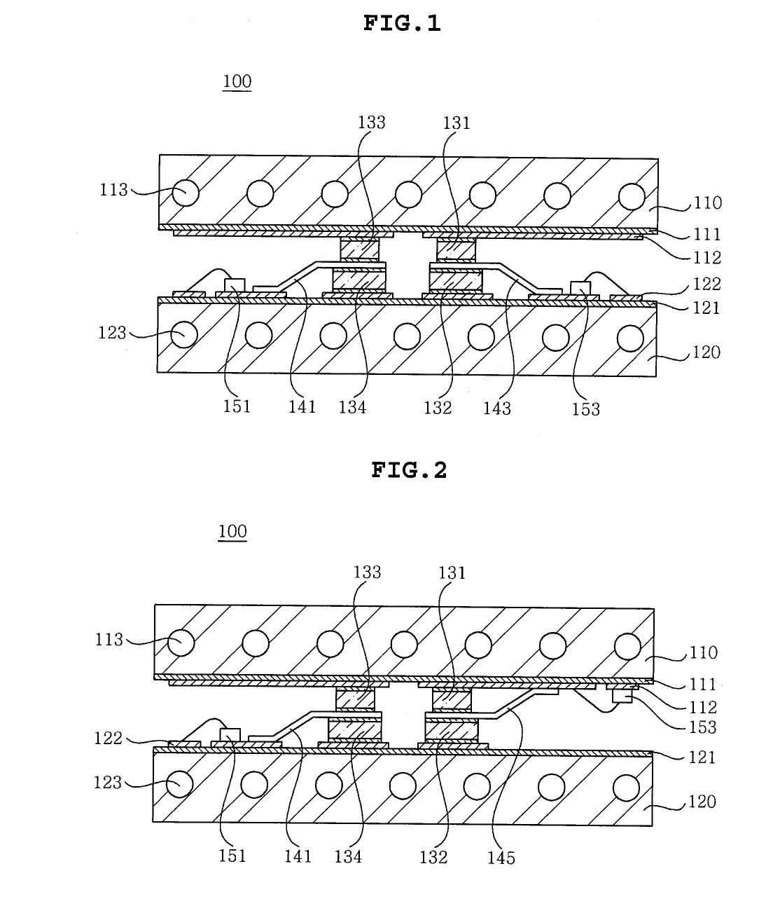

FIG. 1 is a cross-sectional view showing a structure of a power module package according to a first preferred embodiment of the present invention, which will be described with reference to FIG. 4 for explaining a disposition example of semiconductor devices.

As shown in FIG. 1, a power module package 100 includes a heat dissipation plates including a first heat dissipation plate 120 and a second heat dissipation plate 110 disposed to be spaced apart from each other, insulating layers 111 and 121 formed on the heat dissipation plate, metal layers 112 and 122 formed on the insulating layers 111 and 121, semiconductor devices 131, 132, 133, and 134 mounted on the metal layers 112 and 122, and lead spacers 141 and 143 formed to connect the metal layer 122 of the first heat dissipation plate side or the metal layer 112 of the second heat dissipation plate side with the semiconductor layers 131, 132, 133, and 134.

In this configuration, the semiconductor devices 132 and 134 formed on the metal layer 122 of the first heat dissipation plate side and the semiconductor devices 131 and 133 formed on the metal layer 112 of the second heat dissipation plate side may be disposed in a multi-layered type.

In addition, as shown in FIG. 1, sides of the lead spacers 141 and 143 may be formed to connect between the multi-layered semiconductor devices 131, 132, 133, and 134 and the other sides thereof may be formed to connect to the metal layer 122 of the first heat dissipation plate side or the metal layer 112 of the second heat dissipation plate side.

Further, as shown in FIG. 1, when the multi-layered semiconductor devices are configured with two pairs 131 and 132 and 133 and 134 and the lead spacers 141 and 143 include the first lead spacer 141 and the second spacer 143, sides of the first and second lead spacers 141 and 143 may each be formed to connect between the multi-layered semiconductor devices 131 and 132 and 133 and 134 and the other sides thereof may be formed to connect to the metal layer 122 of the first heat dissipation plate side.

Meanwhile, the heat dissipation plates 110 and 120 may further include cooling channels 113 and 123 formed so that a cooling material may flow in the heat dissipation plate.

For example, the cooling material may be water or a refrigerant but is not limited thereto.

In addition, the cooling channels 113 and 123 may be formed at a center of the heat dissipation plate based on a thickness direction of the heat dissipation plates 110 and 120.

Meanwhile, the semiconductor devices 131, 132, 133, and 134 include power devices 132 and 134 and control devices 131 and 133. The power devices 132 and 134 may be mounted on the metal layer 122 of the first heat dissipation plate side and the control devices 131 and 133 may be mounted on the metal layer 112 of the second heat dissipation plate side.

Meanwhile, when the semiconductor devices 131, 132, 133, and 134 include the power devices 132 and 134 and the control devices 131 and 133 and the multi-layered semiconductor devices are configured with two pairs, the power devices 132 and 134 may each be mounted on the metal layer 122 of the first heat dissipation plate side or on the metal layer 112 of the second heat dissipation plate side.

In addition, the control devices 131 and 133 may each be mounted on the metal layer 122 of the first heat dissipation plate side or the metal layer 112 of the second heat dissipation plate side.

For example, as shown in FIG. 1, the power devices may each be mounted on the metal layer 122 of the first heat dissipation plate side and the control devices may each be mounted on the metal layer 112 of the second heat dissipation plate side, but as shown in FIG. 4, a combination of the power devices and the control devices may be mounted on the metal layer 122 of the first heat dissipation plate side and the metal layer 112 of the second heat dissipation plate side, respectively.

Since the structure of the power module package 100 according to the exemplary embodiment of the present invention is a structure in which the heat dissipation plates are disposed on the top and bottom portions, heat generated from the semiconductor devices 131, 132, 133, and 134 may be more effectively emitted, such that a freedom of disposition of the semiconductor devices 131, 132, 133, and 134 may be improved.

In addition, the semiconductor devices include control devices 151 and 153 and as shown in FIG. 1, the control devices 151 and 153 may be mounted on the metal layer 122 of the first heat dissipation plate side or the metal layer 112 of the second heat dissipation plate side.

Meanwhile, the first and second lead spacers 141 and 143 shown in FIG. 1 may serve to perform electrical connection and an electrical connection passage may be a sequence of the metal layer 122 on the bottom portions of the semiconductor devices 134 and 132, the semiconductor devices 134, and 132, the first and second lead spacers 141 and 143 connected to the semiconductor devices 134 and 132, and the metal layer 122 connected to the first and second lead spacers 141 and 143.

The electrical connection role of the first and second lead spacers may be similarly applied to a second exemplary embodiment and a third exemplary embodiment as described below and the electrical connection passage may correspond to the above-mentioned contents.

Power Module Package-Second Preferred Embodiment

FIG. 2 is a cross-sectional view showing a structure of a power module package according to a second preferred embodiment of the present invention.

However, among components of the second preferred embodiment, a description of the same components as the components of the first preferred embodiment will be omitted, and only the components different therefrom will be described.

As shown in FIG. 2, a power module package 100 includes a heat dissipation plates including a first heat dissipation plate 120 and a second heat dissipation plate 110 disposed to be spaced apart from each other, insulating layers 111 and 121 formed on the heat dissipation plate, metal layers 112 and 122 formed on the insulating layers 111 and 121, semiconductor devices 131, 132, 133, and 134 mounted on the metal layers 112 and 122, and lead spacers 141 and 145 formed to connect the metal layer 122 of the first heat dissipation plate side or the metal layer 112 of the second heat dissipation plate side with the semiconductor layers 131, 132, 133, and 134.

In this configuration, the semiconductor devices 132 and 134 formed on the metal layer 122 of the first heat dissipation plate side and the semiconductor devices 131 and 133 formed on the metal layer 112 of the second heat dissipation plate side may be disposed in a multi-layered type.

In addition, as shown in FIG. 2, when the multi-layered semiconductor devices are configured with two pairs 131 and 132 and 133 and 134 and the lead spacers include the first lead spacer 141 and the second lead spacer 145, sides of the first lead spacer 141 may be formed to connect between the multi-layered semiconductor devices 133 and 134 and the other sides thereof may be formed to connect to the metal layer 122 of the first heat dissipation plate side, and one side of the second lead spacer 145 may be formed to connect between the multi-layered semiconductor devices 131 and 132 and the other side thereof may be formed to connect to the metal layer 112 of the second heat dissipation plate side.

Power Module Package-Third Preferred Embodiment

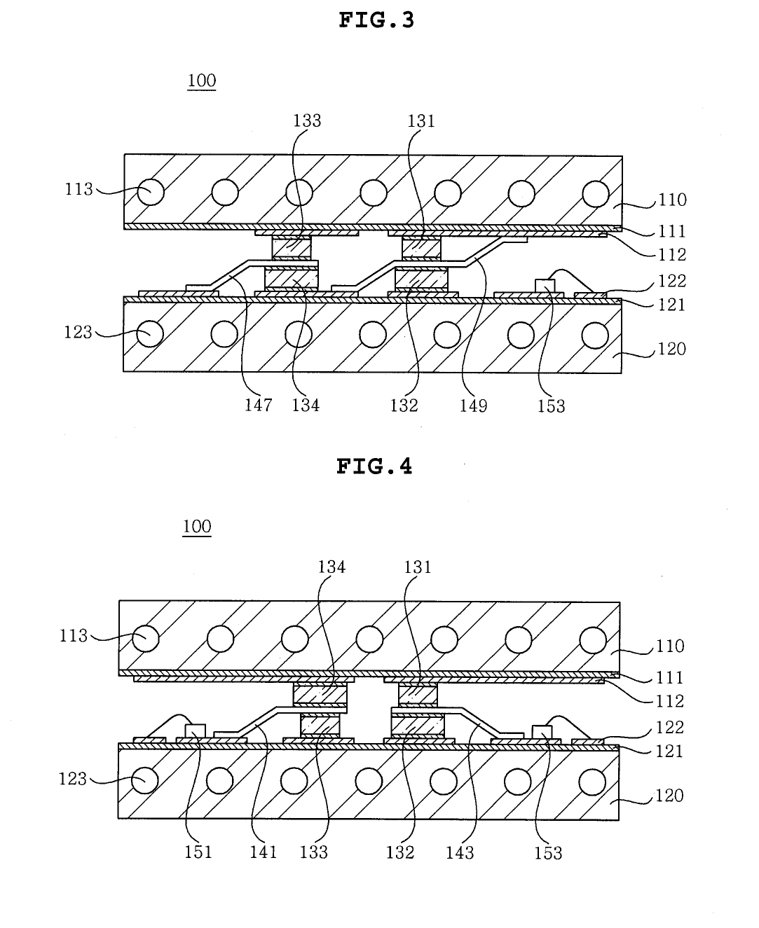

FIG. 3 is a cross-sectional view showing a structure of a power module package according to a third preferred embodiment of the present invention.

However, among components of the third preferred embodiment, a description of the same components as the components of the first preferred embodiment will be omitted, and only the components different therefrom will be described.

As shown in FIG. 3, a power module package 100 includes a heat dissipation plates including a first heat dissipation plate 120 and a second heat dissipation plate 110 disposed to be spaced apart from each other, insulating layers 111 and 121 formed on the heat dissipation plate, metal layers 112 and 122 formed on the insulating layers 111 and 121, semiconductor devices 131, 132, 133, and 134 mounted on the metal layers 112 and 122, and lead spacers 147 and 149 formed to connect the metal layer 122 of the first heat dissipation plate side or the metal layer 112 of the second heat dissipation plate side with the semiconductor layers 131, 132, 133, and 134.

In this configuration, one side of the lead spacer 149 may be formed to connect to the metal layer 122 of the first heat dissipation plate side, a central region thereof may be formed to be inserted between the multi-layered semiconductor devices 131 and 132, and the other side thereof may be formed to connect to the metal layer 112 of the second heat dissipation plate side.

In addition, as shown in FIG. 3, when the multi-layered semiconductor devices 131, 132, 133, and 134 are configured with two pairs and the lead spacer includes the first lead spacer 147 and the second lead spacer 149, one side of the first lead spacer 147 may be formed to connect between the multi-layered semiconductor devices 133 and 134 and the other side thereof may be formed to connect to the metal layer 122 of the first heat dissipation plate side.

Further, one side of the second lead spacer 149 may be formed to connect to the metal layer 122 of the first heat dissipation plate side, a central region thereof may be formed to be inserted between the multi-layered semiconductor devices 131 and 132, and the other side thereof may be formed to connect to the metal layer 112 of the second heat dissipation plate side.

Method for Manufacturing Power Module Package

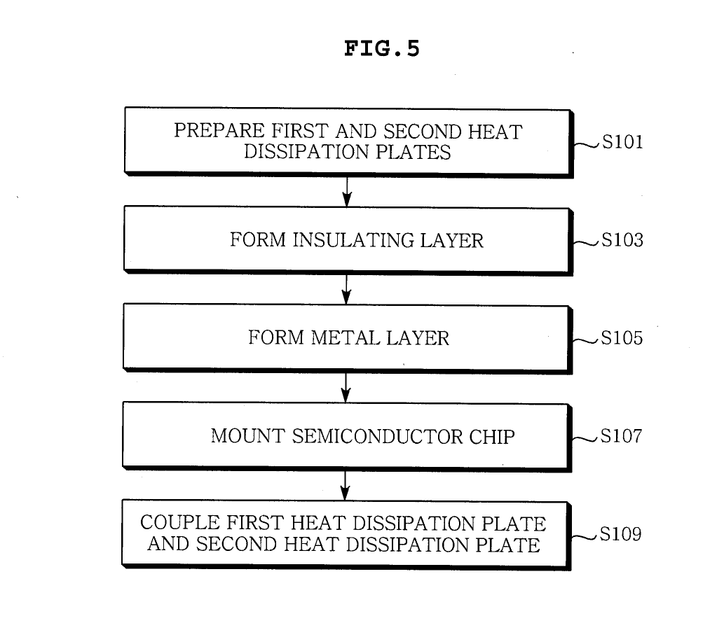

FIG. 5 is a flow chart for explaining a method for manufacturing a power module package according to the preferred embodiment of the present invention, which will be described with reference to FIGS. 1 to 4 as described.

First, as shown in FIG. 5, the heat dissipation plate including the first heat dissipation plate (120 of FIG. 1) and the second heat dissipation plate (110 of FIG. 1) is prepared (S101).

Although not shown, at step S101, a step of forming the cooling channels 113 and 123 so as to move the cooling material to the inside of the heat dissipation plates 110 and 120 may be further provided.

Next, the insulating layers 121 and 111 are formed on the heat dissipation plates 120 and 110 (S103).

In this case, the insulating layers 121 and 111 may be a ceramic insulating layer made of aluminum oxide (Al₂O₃), aluminum nitride (AlN), silicon nitride (SiN), boron nitride (BN), or the like, but is not limited thereto.

In addition, the insulating layers 121 and 111 may use a spray coating method, a screen printing method, a dipping method, a spin coating method, or the like, but is not limited thereto.

Next, the metal layers 122 and 112 are formed on the insulating layers 121 and 111 (S105).

In this case, the metal layers 122 and 112 may be formed by a method of forming a thin seed layer on the insulating layers 121 and 111 by using dry sputter or wet electroless plating, multi-layering the metal layers having a desired thickness by using wet plating, and then forming a circuit pattern by chemical etching, but is not limited thereto.

In this case, the seed layer may be made of titanium (Ti), copper (Cu), nickel-chromium (NiCr), tungsten (W), nickel (Ni), or a combination thereof, but is not limited thereto.

Next, the semiconductor devices 131, 132, 133, and 134 are mounted on the metal layers 122 and 112 (S107).

When the semiconductor device includes the power devices 132 and 134 and the control devices 131 and 133, at a step of mounting the semiconductor devices, the power devices 132 and 134 may be mounted on the metal layer 122 of the first heat dissipation plate side and the control devices 131 and 133 may be mounted on the metal layer 112 of the second heat dissipation plate side.

In addition, when the semiconductor devices include the power devices 132 and 134 and the control devices 131 and 133 and the multi-layered semiconductor devices are configured with two pairs, at a step of mounting the semiconductor devices, the power devices 132 and 134 may each be mounted on the metal layer 122 of the first heat dissipation plate side or on the metal layer 112 of the second heat dissipation plate side.

In addition, the control devices 131 and 133 may each be mounted on the metal layer 122 of the first heat dissipation plate side or the metal layer 112 of the second heat dissipation plate side.

Next, the lead spacers 141 and 143 are formed so as to connect the first heat dissipation plate 120 or the second heat dissipation plate 110 to the semiconductor devices 131, 132, 133, and 134 to couple the first heat dissipation plate 120 and the second heat dissipation plate 110 and the second heat dissipation plate 110 is disposed on the first heat dissipation plate 120 so as to be spaced apart from the first heat dissipation plate 120 (S109).

In this configuration, the semiconductor devices 132 and 134 formed on the metal layer 122 on the first heat dissipation plate side and the semiconductor devices 131 and 133 formed on the metal layer 112 on the second heat dissipation plate side may be disposed in a multi-layered type.

In addition, the lead spacers 141 and 143 may be made of copper (Cu), aluminum (Al), nickel (Ni), or iron (Fe), but is not limited thereto. Therefore, the lead spacers 141 and 143 may be made of all the metal materials.

Meanwhile, the lead spacers 141 and 143 according to the exemplary embodiment of the present invention may be bonded to the semiconductor devices or the metal layers through solder, an adhesive of a metal material, silver (Ag) paste, copper paste, or the like.

At step S109, as shown in FIG. 1, sides of the lead spacers 141 and 143 may be formed to connect between the multi-layered semiconductor devices 131, 132, 133, and 134 and the other sides thereof may be formed to connect to the metal layer 122 of the first heat dissipation plate side or the metal layer 112 of the second heat dissipation plate side.

Further, as shown in FIG. 1, when the multi-layered semiconductor devices are configured with two pairs 131 and 132 and 133 and 134 and the lead spacer includes the first lead spacer 141 and the second lead spacer 143, the sides of the first and second lead spacers 141 and 143 may each be formed to connect between the multi-layered semiconductor devices 131 and 132 and 133 and 134 and the other sides thereof may be formed to connect to the metal layer 122 on the first heat dissipation plate side.

Further, as shown in FIG. 2, when the multi-layered semiconductor devices are configured with two pairs 131 and 132 and 133 and 134 and the lead spacer includes the first lead spacer 141 and the second lead spacer 145, the sides of the first lead spacers 141 may be formed to connect between the multi-layered semiconductor devices 133 and 134 and the other sides thereof may be formed to connect to the metal layer 122 on the first heat dissipation plate side.

In addition, the one side of the second lead spacer 145 may be formed to connect between the multi-layered semiconductor devices 131 and 132 and the other side thereof may be formed to connect to the metal layer 112 of the second heat dissipation plate side.

At step S109, as shown in FIG. 3, the one side of the lead spacer may be formed to connect to the metal layer 122 of the first heat dissipation plate side, the central region thereof may be formed to be inserted between the multi-layered semiconductor devices 131 and 132, and the other side thereof may be formed to connect to the metal layer 112 of the second heat dissipation plate side.

In addition, at step S109, as shown in FIG. 3, when the multi-layered semiconductor devices are configured with two pairs and the lead spacer includes the first lead spacer 147 and the second lead spacer 149, one side of the first lead spacer 147 may be formed to connect between the multi-layered semiconductor devices 133 and 134 and the other side thereof may be formed to connect to the metal layer 122 of the first heat dissipation plate side.

Further, one side of the second lead spacer 149 may be formed to connect to the metal layer 122 of the first heat dissipation plate side, the central region thereof may be formed to be inserted between the multi-layered semiconductor devices 131 and 132, and the other side thereof may be formed to connect to the metal layer 112 of the second heat dissipation plate side.

The power module package according to the exemplary embodiment of the present invention can maximize the cooling efficiency due to the structure in which the heat dissipation plates are formed on the top and bottom portions, such that the three-dimensional multi-layer structure of the power devices (for example, insulated gate bipolar transistor (IGBT)) and the control devices (for example, diode) may be implemented, thereby implementing the high integration, miniaturization, and lightness of the power module.

In addition, the power module package according to the exemplary embodiment of the present invention can be manufactured in the integrated type of the electric circuit wirings, that is, the metal layers and the heat dissipation plates to more reduce a thermal resistance interface than that of the related art that is a separated type of the heat dissipation plate from the metal layers, thereby improving the heat dissipation characteristics.

As set forth above, the power module package and the method for manufacturing the same according to the exemplary embodiments of the present invention can more effectively emit heat generated from the semiconductor devices by implementing the cooling channel through which the cooling material flows into the top portion and the bottom portion.

In addition, the exemplary embodiments of the present invention can provide the power module package structure capable of implementing the three-dimensionally high integration by disposing the semiconductor devices each mounted on the top and bottom heat dissipation plates in the multi-layered type since the heat dissipation plates disposed on the top and bottom portions serve as the substrate.

Further, the exemplary embodiments of the present invention can secure the space for forming the wire, or the like, and serve to transfer electricity through the lead spacer by forming the lead spacer between the top and bottom heat dissipation plates to connect between the heat dissipation plates with the semiconductor devices.

Although the embodiment of the present invention has been disclosed for illustrative purposes, it will be appreciated that a power module package and a method for manufacturing the same according to the invention are not limited thereby, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A power module package, comprising:
a heat dissipation plate including a first heat dissipation plate and a second heat dissipation plate disposed to be spaced apart from each other;
insulating layers formed on the heat dissipation plate;
metal layers formed on the insulating layers;
semiconductor devices mounted on the metal layers; and
lead spacers formed to connect the metal layer of the first heat dissipation plate side or the metal layer of the second heat dissipation plate side with the semiconductor layers,
wherein the semiconductor devices formed on the metal layers of the first heat dissipation plate side and the semiconductor devices formed on the metal layer of the second heat dissipation plate side are disposed in a multi-layered type.

2. The power module package as set fort in claim 1, wherein one side of the lead spacer is formed to connect between the multi-layered semiconductor devices and the other side thereof is formed to connect to the metal layer of the first heat dissipation plate side or the metal layer of the second heat dissipation plate side.

3. The power module package as set fort in claim 2, wherein when the multi-layered semiconductor devices are configured with two pairs and the lead spacer includes a first lead spacer and a second lead spacer,
sides of the first and second lead spacers are formed to connect between the multi-layered semiconductor devices and the other sides thereof are formed to connect to the metal layer of the first heat dissipation plate side.

4. The power module package as set fort in claim 2, wherein when the multi-layered semiconductor devices are configured with two pairs and the lead spacer includes the first lead spacer and the second lead spacer,
one side of the first lead spacer is formed to connect between the multi-layered semiconductor devices and the other side thereof is formed to connect to the metal layer of the first heat dissipation plate side, and
one side of the second lead spacer is formed to connect between the multi-layered semiconductor devices and the other side thereof is formed to connect to the metal layer of the second heat dissipation plate side.

5. The power module package as set fort in claim 1, wherein one side of the lead spacer is formed to connect to the metal layer of the first heat dissipation plate side, a central region thereof is formed to be inserted between the multi-layered semiconductor devices, and the other side thereof is formed to connect to the metal layer of the second heat dissipation plate side.

6. The power module package as set fort in claim 1, wherein when the multi-layered semiconductor devices are configured with two pairs and the lead spacer includes the first lead spacer and the second lead spacer,
one side of the first lead spacer is formed to connect between the multi-layered semiconductor devices and the other side thereof is formed to connect to the metal layer of the first heat dissipation plate side, and
one side of the second lead spacer is formed to connect to the metal layer of the first heat dissipation plate side, a central region thereof is formed to be inserted between the multi-layered semiconductor devices, and the other side thereof is formed to connect to the metal layer of the second heat dissipation plate side.

7. The power module package as set fort in claim 1, further comprising a cooling channel formed so as to move a cooling material to the inside of the heat dissipation plate.

8. The power module package as set fort in claim 7, wherein the cooling channel is formed at a center of the heat dissipation plate based on a thickness direction of the heat dissipation plate.

9. The power module package as set fort in claim 1, wherein the semiconductor device includes power devices and control devices, and
the power devices are mounted on the metal layer of the first heat dissipation plate side and the control devices are mounted on the metal layer of the second heat dissipation plate side.

10. The power module package as set fort in claim 1, wherein when the semiconductor device include power devices and control devices and the multi-layered semiconductor devices are configured with two pairs,
the power devices are each mounted on the metal layer of the first heat dissipation plate side or the metal layer of the second heat dissipation plate side, and
the control devices are each mounted on the metal layer of the first heat dissipation plate side or the metal layer of the second heat dissipation plate side.

11. The power module package as set fort in claim 1, wherein the semiconductor devices include control devices and
the control devices are mounted on the metal layer of the first heat dissipation plate side or the metal layer of the second heat dissipation plate side.

12. A method for manufacturing a power module package, comprising:
preparing a heat dissipation plates including a first heat dissipation plate and a second heat dissipation plate;
forming insulating layers on the heat dissipation plate;
forming metal layers on the insulating layers;
mounting semiconductor devices on the metal layers; and
forming lead spacers to connect the first heat dissipation plate or the second heat dissipation plate with the semiconductor devices to couple the first heat dissipation plate and the second heat dissipation plate and disposing the second heat dissipation plate on the first heat dissipation plate so as to be spaced apart from the first heat dissipation plate,
wherein the semiconductor devices formed on the metal layers of the first heat dissipation plate side and the semiconductor devices formed on the metal layer of the second heat dissipation plate side are disposed in a multi-layered type.

13. The method as set forth in claim 12, wherein at the disposing of the second heat dissipation plate on the first heat dissipation plate so as to be spaced apart from the first heat dissipation plate, one side of the lead spacer is formed to connect between the multi-layered semiconductor devices and the other side thereof is formed to connect to the metal layer of the first heat dissipation plate side or the metal layer of the second heat dissipation plate side.

14. The method as set forth in claim 13, wherein when the multi-layered semiconductor devices are configured with two pairs and the lead spacer includes a first lead spacer and a second lead spacer,
sides of the first and second lead spacers are formed to connect between the multi-layered semiconductor devices and the other sides thereof are formed to connect to the metal layer of the first heat dissipation plate.

15. The method as set forth in claim 13, wherein when the multi-layered semiconductor devices are configured with two pairs and the lead spacer includes the first lead spacer and the second lead spacer,
one side of the first lead spacer is formed to connect between the multi-layered semiconductor devices and the other side thereof is formed to connect to the metal layer of the first heat dissipation plate side, and
one side of the second lead spacer is formed to connect between the multi-layered semiconductor devices and the other side thereof is formed to connect to the metal layer of the second heat dissipation plate side.

16. The method as set forth in claim 12, wherein at the disposing of the second heat dissipation plate on the first heat dissipation plate so as to be spaced apart from the first heat dissipation plate, one side of the lead spacer is formed to connect to the metal layer of the first heat dissipation plate side, a central region thereof is formed to be inserted between the multi-layered semiconductor devices, and the other side thereof is formed to connect to the metal layer of the second heat dissipation plate side.

17. The method as set forth in claim 12, wherein at the disposing of the second heat dissipation plate on the first heat dissipation plate so as to be spaced apart from the first heat dissipation plate,
when the multi-layered semiconductor devices are configured with two pairs and the lead spacer includes the first lead spacer and the second lead spacer,
one side of the first lead spacer is formed to connect between the multi-layered semiconductor devices and the other side thereof is formed to connect to the metal layer of the first heat dissipation plate side, and
one side of the second lead spacer is formed to connect to the metal layer of the first heat dissipation plate side, a central region thereof is formed to be inserted between the multi-layered semiconductor devices, and the other side thereof is formed to connect to the metal layer of the second heat dissipation plate side.

18. The method as set forth in claim 12, further comprising: at the preparing of the heat dissipation plate, forming a cooling channel so as to move a cooling material to the inside of the heat dissipation plate.

19. The method as set forth in claim 12, wherein at the mounting of the semiconductor device,
when the semiconductor device includes power devices and control devices,
the power devices are mounted on the metal layer of the first heat dissipation plate side and the control devices are mounted on the metal layer of the second heat dissipation plate side.

20. The method as set forth in claim 12, wherein at the mounting of the semiconductor devices,
when the semiconductor devices include power devices and control devices and the multi-layered semiconductor devices are configured with two pairs,
the power devices are each mounted on the metal layer of the first heat dissipation plate side or the metal layer of the second heat dissipation plate side, and
the control devices are each mounted on the metal layer of the first heat dissipation plate side or the metal layer of the second heat dissipation plate side.
